(19) United States
(12) Patent Application Publication
(10) Pub. No.: US 2019/0241284 A1
(43) Pub. Date: Aug. 8, 2019

(54) APPARATUS AND METHOD FOR TESTING ELECTROMAGNETIC INTERFERENCE DEVICES WITHIN A LINE REPLACEABLE UNIT

(71) Applicant: Parker-Hannifin Corporation, Cleveland, OH (US)

(72) Inventor: Robert Samuel Benward, Huntington Station, NY (US)

(21) Appl. No.: 16/250,202

(22) Filed: Jan. 17, 2019

Related U.S. Application Data
(60) Provisional application No. 62/627,856, filed on Feb. 8, 2018.

(51) Int. Cl. B64F 5/60; G01R 31/00; G01R 27/04

(52) U.S. Cl. CPC B64F 5/60; G01R 31/001; H05K 9/0066; G01R 27/04; G01R 31/008

(57) ABSTRACT

A system and method for testing a network of electromagnetic interference components within a unit under test (UUT) of an aircraft, the UUT having at least one of an input port or an output port electrically coupled to the network, the method including: generating a radio frequency (RF) signal swept over a prescribed frequency range; applying the generated RF signal to the UUT; measuring a resultant signature at the at least one input port or output port; comparing the measured resultant signature with a baseline signature corresponding to the respective at least one input port or output port, the baseline signature representing normal operation of the UUT; and determining the UUT is out of specification when the measured signal and the baseline signature do not correspond to one another within a prescribed envelope.

### FIELD OF THE DISCLOSURE

The present disclosure relates generally to testing electrical equipment in an aircraft, and more particularly, to a method and system for testing electromagnetic interference devices within a line replaceable unit of an aircraft.

### BACKGROUND

Commercial or military aircraft use line replaceable units (LRUs) for logistical and operational purposes. As used herein, an LRU is defined as an electronic support item which is removed and replaced at the field level to restore the end item to an operational ready condition. An LRU is typically a sealed device that includes sensitive electrical components such as radio frequency (RF) components, circuits or other devices, which may be essential to logistics and operation of an aircraft. An LRU is generally designed to specifications according to Aeronautical Radio, Incorporated (ARINC) standards, and also to interface with other electrical devices operated under strict military or other institutional standards. Hence, it is important to determine when an LRU is not operating within specification and, if so, to remove and replace the LRU.

An electromagnetic interference (EMI) event may lead to problems regarding electromagnetic compatibility (EMC) within the LRU or external to the LRU. An EMC problem within the LRU includes radiated emissions produced by the electrical components within the LRU due to, e.g., inductive switching. Radiated emissions that are not sufficiently filtered within the LRU may degrade or destroy the electrical device(s) within the LRU.

An EMC problem detected externally to the LRU includes radiated & conducted emissions, e.g., radiated & conducted emissions within the LRU, conducted to an external cable, such as a signal, data, or power cable, connected to the LRU. Conducted emissions on external line, which can also radiate, may then cause failure of the other LRUs on the same electrical connection, a power supply network, etc.

Excessive transient voltage and current is primarily caused by lightning events. Since the LRU contains electrical devices, to protect against such excessive transient current and voltage the LRU generally includes a transient-protection circuit at an input of the LRU or at the electrical device(s) within the LRU. A transient-protection circuit (also referred to as a transient-voltage suppressor or TVS) may be placed at the input of the LRU or at the electrical device itself within the LRU. The TVS suppresses transient voltages that exceed a rated voltage of the electrical device by clamping an input voltage at a desired voltage level. TVSs may also filter noise (e.g., current spikes) by shunting the current away from the electrical device. In addition, EMI events can be addressed by including filters that reduce RF interference, e.g., inductive switching, or high intensity radiation field.

Due to consequences that may result from conducted emissions, the regulatory agencies have instituted rules and regulations to ensure operational safety. For example, the Federal Aviation Administration (FAA), has issued several directives requiring continued airworthiness of an aircraft. E.g. Advisory Circular No. 33.4-3 issued Sep. 16, 2005 with respect to 14 C.F.R. 33.4, entitled Instructions for Continued Airworthiness; Advisory Circular No. 33.28-1 issued Jun. 29, 2001 providing for compliance criteria for 14 C.R.R. 33.28. These directives provide, in part, guidance for lightning and EMI qualification tests consistent with, e.g., The American Radio Technical Commission for Aeronautics DO-160. Under these directives, the FAA regulates continued airworthiness of an aircraft by testing an LRU placed within the aircraft for EMC. The FAA permits the lightning and EMI components to defer verification testing if the individual failure rate of a single component is two orders of magnitude greater than the overall Meantime between Failure (MTBF) of the LRU. However, the FAA deference is only temporary, and verification of these EMI components is required to be performed every time the LRUs return to the factory as part of the manufacturer's Acceptance Test Procedure (ATP).

### SUMMARY

It would be desirable to develop a method and system for testing a network of lightning and EMI components arranged within an LRU (also referred to as a unit under test or UUT) as part of the ATP, without disassembling the UUT during the test procedure.

A method according to the present disclosure can test the UUT for EMI component health without the need to disassemble the UUT. The method reduces unnecessary exposure of the network, and thus, the lightning and EMI components (hereinafter, also referred to as the EMI components) of the network, to external stresses, e.g., unnecessarily subjecting the EMI components to excessive voltage due to a tester touching the EMI component after becoming statically charged. Further, the method according to the present disclosure increases the efficiency of the ATP testing by simplifying the testing procedure.

One aspect of the present disclosure relates to a method for testing a network of electromagnetic interference components within a unit under test (UUT) of an aircraft, the UUT having at least one of an input port or an output port electrically coupled to the network, the method including generating a radio frequency (RF) signal swept over a prescribed frequency range; applying the generated RF signal to the UUT; measuring a resultant signature at the at least one input port or output port; comparing the measured resultant signature with a baseline signature corresponding to the respective at least one input port or output port, the baseline signature representing normal operation of the UUT; and determining the UUT is out of specification when the measured signal and the baseline signature do not correspond to one another within a prescribed envelope.

Optionally, measuring comprises using a signal generator/analyzer to analyze the resultant signature.

Optionally, generating the RF signal includes using a tracking generator to generate the RF signal at a frequency the signal generator/analyzer is tuned.

Optionally, generating an RF signal includes using a broadband noise generator to generating the RF signal.

Optionally, using the broadband noise generator comprises using a broadband noise generator arranged within the UUT.

Optionally, measuring the resultant signature includes measuring a return loss of the applied generated RF signal over the prescribed frequency range.

Optionally, the baseline signature comprises a return loss measured over the prescribed frequency range of a known good UUT.

Optionally, applying generated RF signal comprises applying the generated RF signal to the UUT when power is removed from the UUT.

Optionally, applying the generated RF signal comprises using an antenna to apply the generated RF signal to the UUT.

Optionally, using the antenna comprises using an antenna arranged within the UUT.

Another aspect relates to a method for testing an electromagnetic interference component within a unit under test (UUT) of an aircraft, the UUT having at least one of an input port or an output port electrically coupled to the electromagnetic interference component, the method including applying to the at least one input port or output port a radio frequency signal swept over a prescribed frequency range; measuring at the at least one input port or output port a return loss over the prescribed frequency range; comparing the measured return loss with a baseline signature for the respective at least one input port or output port, the baseline signature representing a normal operation of the UUT; and determining the UUT is out of specification when the measured return loss and the baseline signature differ by more than a prescribed value.

Optionally, measuring includes using a signal generator/analyzer to analyze the resultant signature.

Optionally, measuring the resultant signature includes measuring a return loss of the applied generated RF signal over the prescribed frequency range.

Optionally, the baseline signature includes a return loss measured over the prescribed frequency range of a known good UUT.

Optionally, applying generated RF signal includes applying the generated RF signal to the UUT when power is removed from the UUT.

Another aspect relates to a system for testing a network of electromagnetic interference and lightning components within a unit under test (UUT) of an aircraft, including a signal generator configured to generate a radio frequency (RF) signal swept over a prescribed frequency range; circuitry configured to input a generated radio frequency signal into UUT, the circuitry electrically couplable to at least one input or output port of the UUT; and a device operably coupled to the circuitry and the at least one input or output port of the UUT and configured to measure and compare a resultant signature detected at the at least one input or output port of the UUT to a baseline signature corresponding to the respective at least one input port or output port, the baseline signature representing normal operation of the UUT.

Optionally, a directional coupler is electrically couplable to the circuitry, the at least one input or output port of the UUT, and the device.

Optionally, an antenna is operably coupled to the circuitry and configured to apply the generated radio frequency signal into the UUT.

Another aspect relates to a system for testing an electromagnetic interference component within a unit under test (UUT) of an aircraft, including circuitry configured to input a radio frequency signal swept over a prescribed frequency range into an at least one input or output port of the UUT, the circuitry electrically coupleable to at least one input or output port of the UUT; and a device operably coupled to the circuitry and the at least one input or output port of the UUT and configured to measure and compare a resultant signature detected at the at least one input or output port of the UUT to a baseline signature corresponding to the respective at least one input port or output port, the baseline signature representing normal operation of the UUT.

Optionally, a directional coupler is electrically coupleable to the circuitry, the at least one input or output port of the UUT, and the device.

These and further features of the present disclosure will be apparent with reference to the following description and attached drawings. In the description and drawings, particular embodiments of the present disclosure have been presented in detail as being indicative of some of the ways in which the principles of the disclosure may be employed, but it is understood that the disclosure is not limited correspondingly in scope. Rather, the disclosure includes all changes, modifications and equivalents coming within the scope of the claims appended hereto.

Features that are described and/or illustrated with respect to one embodiment may be used in the same way or in a similar way in one or more other embodiments and/or in combination with or instead of the features of the other embodiments.

### BRIEF DESCRIPTION OF THE DRAWINGS

In the annexed drawings:

FIG. 1 illustrates an exemplary line replaceable unit (LRU) within an aircraft showing a testing configuration for EMC at an operation site.

FIG. 2 is an exemplary transient protection circuit within an LRU for suppressing transient energy.

FIG. 3 is a block diagram of an exemplary system for EMC testing of lightning and EMI components within an LRU using a return loss bridge in accordance with the present disclosure.

FIGS. 4A-4B are block diagrams of exemplary systems for EMC testing of a network of lightning and EMI components within an LRU in accordance with the present disclosure. FIG. 4A shows a block diagram of a second exemplary system using an antenna for flooding a swept radio frequency signal over a predetermined frequency range in the LRU. FIG. 4B shows a block diagram of a third exemplary system using a broadband noise generator arranged within the LRU for generating noise within the LRU.

FIG. 5 is an exemplary baseline signature of a known good LRU.

FIGS. 6A-6E are exemplary resultant signatures after EMC testing of lightning and EMI components within an LRU having the exemplary transient protection circuit of FIG. 2 in accordance with the present disclosure. FIG. 6A shows an exemplary resultant signature when a ferrite bead is shorted. FIG. 6B shows a second exemplary resultant signature when a first parallel capacitor is shorted. FIG. 6C shows a third exemplary resultant signature when a second capacitor is shorted. FIG. 6D shows a fourth exemplary resultant signature when the first parallel capacitor is open. FIG. 6E shows a fifth exemplary resultant signature when the second parallel capacitor is open.

FIG. 7 is a flow chart depicting the steps of an exemplary method for obtaining a baseline signature of a network of lightning and EMI components within an LRU in accordance with the present disclosure.

FIG. 8 is a flow chart depicting the steps of an exemplary method for EMC testing of a network of lightning and EMI components within an LRU in accordance with the present disclosure.

FIG. 9 is a flow chart depicting the steps of an exemplary method for EMC testing an LRU using the exemplary system of FIG. 4A in accordance with the present disclosure.

FIG. 10 is a flow chart depicting the steps of a third exemplary method for testing an LRU using the exemplary system of FIG. 4B in accordance with the present disclosure.

### DESCRIPTION

The embodiments of the present disclosure provide a method and system for testing a network of lightning and EMI components within a unit under test (UUT), such as a line replaceable unit (LRU) of an aircraft for EMC without having to disassemble the UUT.

Referring now to the drawings, wherein like reference numerals refer to like parts in the several figures, and primed reference numerals represent parts that are the same or similar to parts that are designated by the same unprimed reference numerals, and wherein the illustrations are somewhat schematic and not necessarily to scale, but are presented to provide together with the description herein an understanding of various features of this disclosure, embodiments of the disclosure are described.

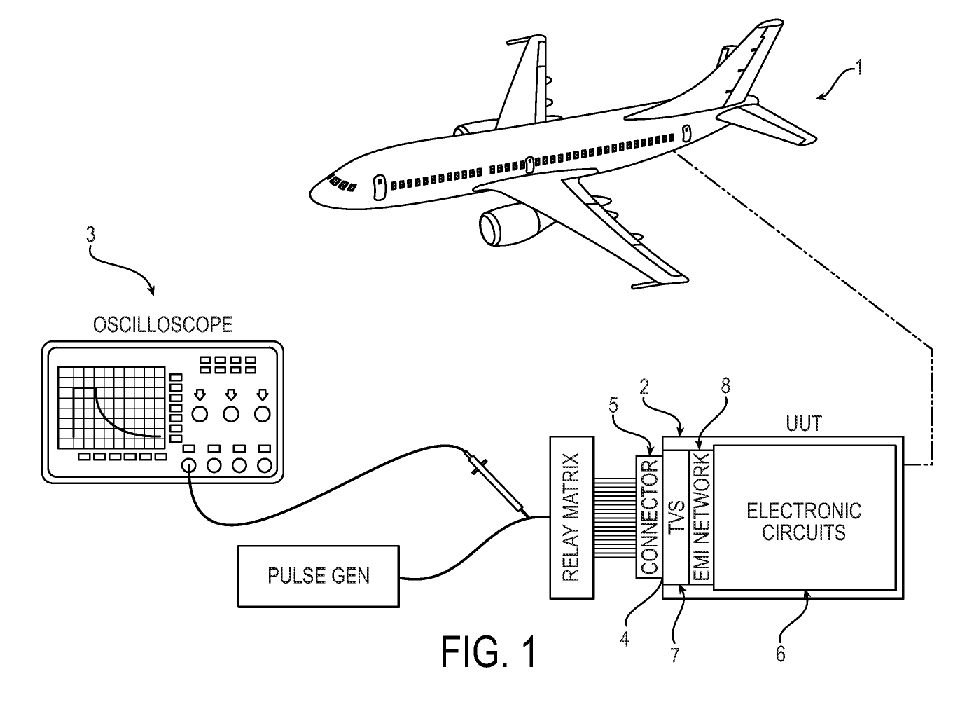

FIG. 1 shows an aircraft 1 having an exemplary UUT in the form of an LRU 2, electrically coupled to a testing system 3 for EMC testing at an operation or testing site. The UUT 2 includes an input and/or output port 4, a connector 5 connected to the input and/or output port 4, one or more electrical circuits 6, and one or more TVSs 7 and a network 8 of EMI components. The input or output port 4, via the connector 5, electrically couples the UUT 2 to the testing system 3 for receiving from the testing system 3 a radio frequency signal swept over a prescribed frequency range (e.g., 100 KHz to 100 MHz). Hence, the RF signal is input to the UUT 2 and the electrical circuit 6 is exposed to such RF signal. The TVSs 7 are arranged at inputs of the UUT 2 or at each electrical circuit 6 and are operative to suppress and filter transient voltages and/or currents. The RF signal is thus suppressed and/or filtered by the TVSs 7 as the RF signal enters the UUT and/or as it reaches the electrical circuit 6, and a reflection of the suppressed and/or filtered RF signal then exits the UUT 2 via the connector 5. In order to determine if TVS or the components therein are operating properly, the testing system 3 obtains the exiting RF signal (also referred to as a return RF signal) via the connector 5, which electrically couples the network or the EMI components of the TVS 7 & network 8 to the testing system 3. The testing system 3 thereafter analyzes the return RF signal based on a method used for EMC determination and creates a resultant signature representative of relevant data in accordance with the analysis method.

For example, an EMC test using a return loss method (discussed in further detail below) may create a resultant signature representative of the reflections of the RF signal measured over the prescribed frequency range. Upon measuring the resultant signature, the testing system 3 compares the resultant signature with a baseline signature of a known good LRU having the same specification as the UUT 2. The baseline signature is representative of return loss measured over the prescribed frequency range of the known good LRU. The testing system 3 then provides the comparison result via an output device, for example, graphically or numerically. Based on the comparison result, it is determined if the UUT 2 is out of the specification. If it is concluded that the UUT 2 is out of specification, then maintenance may be performed and/or it may be removed and replaced with another LRU having the same specification as the UUT 2. The UUT 2 may be deemed out of the specification when the resultant signature and the baseline signature do not correspond to one another within a prescribed envelope. In context of the present disclosure, the predefined envelope may be defined as an acceptable range around the baseline signature of the known good LRU having the same specification as the UUT 2. In one embodiment, the acceptable range is plus or minus twenty percent of the baseline signature values, and in another embodiment the acceptable range is plus or minus ten percent of the baseline signature values, and in yet another embodiment the acceptable range is plus or minus five percent of the baseline signature values.

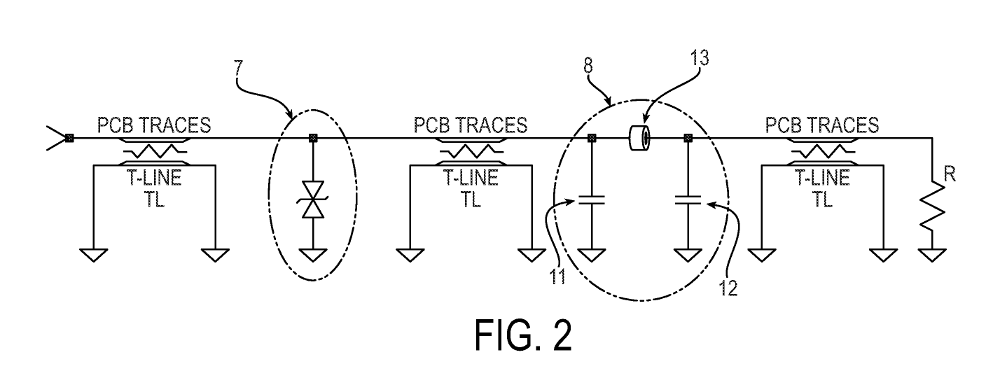

FIG. 2 represents a typical input circuit for both lightning and EMI protection (a transient protection circuit or TVS 7 & NETWORK 8) that includes a standard Transorb/capacitor/bead arrangement. The TVS provides transient protection (lighting, electrostatic discharge, etc. typically in the 100V-1000V range) while the network 8 filters electromagnetic interference and filters both incoming and outgoing noise, typically <100 mV range). A TVS may be any device that operates as a peak limiter, such as, for example, a high power Zener diode. The TVS provides some additional filtering (EMI, not transient) by the nature of their junction capacitance, while the “network” provides the bulk of the “designed in” EMI filtering.

It should be appreciated that other circuit configurations for lightning and EMI protection are possible, and the circuit shown in FIG. 2 is not intended to limit the scope of the invention. The arrangement includes a Transorb 7, shunt capacitors 11, 12, and a ferrite bead 13 all interconnected via transmission lines TL to a load (represented by resistor R). The Transorb 7 clamps an upper or lower extreme of an input signal to a specified voltage level, i.e., a clamping voltage. When a transient voltage is present at the input or output port 4 of the UUT 2 that exceeds a threshold level, the Transorb 7 reduces its resistance to maintain a constant, low clamping voltage. Capacitors 11, 12 shunt excess current induced as a result of the transient voltage. These parallel capacitors 11, 12 bypass excess current from the load and decouple an unwanted current path created by the transient voltage. The ferrite bead 13 suppresses high-frequency noise, and restricts excess current from flowing through at least some of the elements. Absent the ferrite bead 13, excess current may simply flow through resistor R, effectively muting a clamping function performed by the Transorb 7 and filtering performed by the shunt capacitors 11, 12.

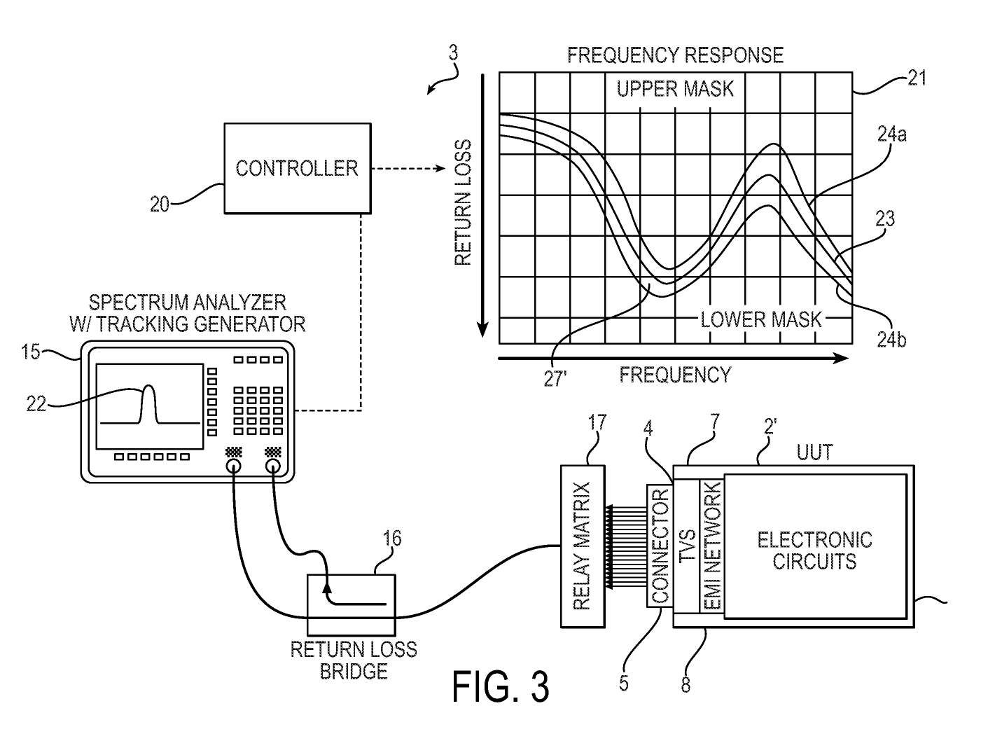

FIG. 3 is a block diagram of an exemplary testing system 3 for performing an EMC test, particularly a radiated emissions test, of the EMI components within a second exemplary UUT 2′ using a return loss method in accordance with the invention. In this embodiment, the EMI components of the TVS 7 & NETWORK 8 are tested for radiated emissions.

Return loss vs. frequency is a signature of a particular circuit which, if manufacturing is consistent, will be repeatable from unit to unit. Any failure in components in the EMI chain should be detectable. A return loss method measures reflections of the RF signal over a prescribed frequency range, and may be used to determine if the EMI components of the transient-protection circuit 7 are operating property. Return Loss of a signal may be defined by equation (1):

$$RL ( dB ) = 10 log 10 ( \frac{Pi}{Pr} ) \qquad ( 1 )$$

where RL(dB) is the Return Loss of power in decibels, Pi is the power in the input incident signal, and Pr is the power in the returned or reflected signal. If a circuit presents a perfect 50Ω load impedance to an input circuit having impedance of 50Ω, there should be no reflection. If, however, there are any discontinuities, including discontinuities in the PC trace layouts, there may be some reflection. Since these impedances are frequency dependent and transient-protection circuits are generally not designed as RF transmission lines or RF filters, there may be various reflections over a frequency range. These reflections vs. frequency are referred to as a return loss test and can be used to evaluate an RF circuit for performance over frequency. More particularly, the return loss for an RF signal over a prescribed frequency range can be calculated using equation (1). Based on the calculated return loss over the prescribed frequency range, a resultant signature representative of the return loss over the prescribed range is created. Thereafter, the resultant signature is compared with a baseline signature of a known good LRU having the same specifications as the UUT 2′. Based on the comparison, it can be determined if the EMI components are within specification.

It is noted that the term “return loss” can be misleading. According to the definition, RL=Log(Pi/Pr), if an incident signal is sent out and very little signal returns, the RL ratio is much larger than 1 (note that there is no negative sign, the term loss implies that) and the load is well matched to the characteristic impedance. RL of 1 implies that the load impedance of a system under test is not matched at all (short or open). The logarithmic system is used to express and manage very large ratios (e.g., ratios much larger or much smaller than 1). A large ratio, or the inverse of that same ratio, produce logarithmic numbers differing only in sign, positive for >1 and negative for ratios smaller than 1). Return loss is generally expressed as a positive number but can still be found in literature expressed as a negative number. Regardless, a very low return loss (˜0 dB) is undesirable, and a high return loss, plus or minus, (e.g., +/−30 dB) is desirable.

With continued reference to FIG. 3, the testing system 3 is electrically coupled to the second exemplary UUT 2′ for radiated emissions testing. The testing system 3 includes a signal generator/analyzer 15, a return loss bridge 16 (also known as a direction coupler or directional bridge), a relay matrix 17, a controller 20, and an output device 21, such as a display device, for providing a testing result. The signal generator/analyzer 15 is electrically coupled to the UUT 2′ via the return loss bridge 16 and the relay matrix 17. The signal generator/analyzer 15 may include a spectrum analyzer having a tracking generator for producing desired emissions on the spectrum analyzer tuned frequency.

In operation, the signal generator/analyzer 15 is set to a desired frequency range (also referred to as a prescribed frequency range) that spans at least a frequency range of interest. The prescribed frequency range may be an entire operational range of the signal generator/analyzer 15, or a different range in accordance with regulatory mandates. Once configured, the signal generator/analyzer 15 generates an RF signal swept over the prescribed frequency range. The generated RF signal 22 may be displayed on a screen of the signal generator/analyzer 15. The signal generator/analyzer 15 provides the RF signal 22 to the return loss bridge 16, which separates signals traveling in one direction from signals traveling in the opposite direction. Hence, once connected to the signal generator/analyzer, the return loss bridge 16 allows the signal generator/analyzer 15 to inject a swept RF signal to the UUT 2′ and obtain the reflected signal in response to the injected signal.

Upon generating the RF signal 22 it is input to the input/output port 4 via the return loss bridge 16 and the relay matrix 17. The relay matrix 17 acts as a switch that selectively couples the signal generator/analyzer 15 to each terminal of the input/output port 4 in order to input the RF signal 22 to the UUT 2′. Transient voltage and/or current produced as a result of the RF signal 22 is clamped and/or filtered by the components of the TVS 7 & NETWORK 8, and a portion of the signal is reflected back out of the UUT 2 at the connector 5. The signal generator/analyzer 15, via the relay matrix 17 and the return loss bridge 16, obtains the reflected RF signal exiting the UUT 2′ at the connector 5.

The connector 5 generally includes a connection mechanism, e.g., a pin, for each of the EMI components of the TVS 7. Thus, connector 5 electrically couples each of the EMI components to the signal generator/analyzer via the relay matrix 17 and the return loss bridge 16. The relay matrix 17 allows the signal generator 15 to inject an RF signal and obtain the reflected RF signal (also referred to as a return RF signal) at a pin coupled to each EMI component. Thereafter, the signal generator/analyzer 15, and particularly the controller 20, analyzes the return RF signal relative to the injected signal. The controller 20 may be internal or external to the signal generator/analyzer 15. Examples of an external controller 20 include a PC, a tablet, etc.

Upon analyzing the return RF signal obtained at each EMI component, the controller 20 creates a resultant signature 23 corresponding to the return loss over the prescribed frequency range. The controller 20 then compares the resultant signature 23 with a baseline signature of the known good LRU having the same specifications as the UUT 2′. The baseline signature may be stored, for example, in a memory within the signal generator/analyzer 15, the controller 20, or in a remote location that is accessible by the signal generator/analyzer 15 and/or controller 20. The controller 20 then causes the output device 21 to provide the comparison result either graphically or numerically. The output device 21 may be a display integrated with or separate from the controller 20. If the resultant signature 23 corresponds with the baseline signature within a prescribed envelope 24a, 24b, then it can be concluded that the EMI components of the UUT 2′ are within specification, and thus, fully operational. If, however, the resultant signature 23 does not correspond to the baseline signature within the prescribed envelope 24a, 24b, it can be concluded that the UUT 2′ is out of specification and maintenance action should be commenced.

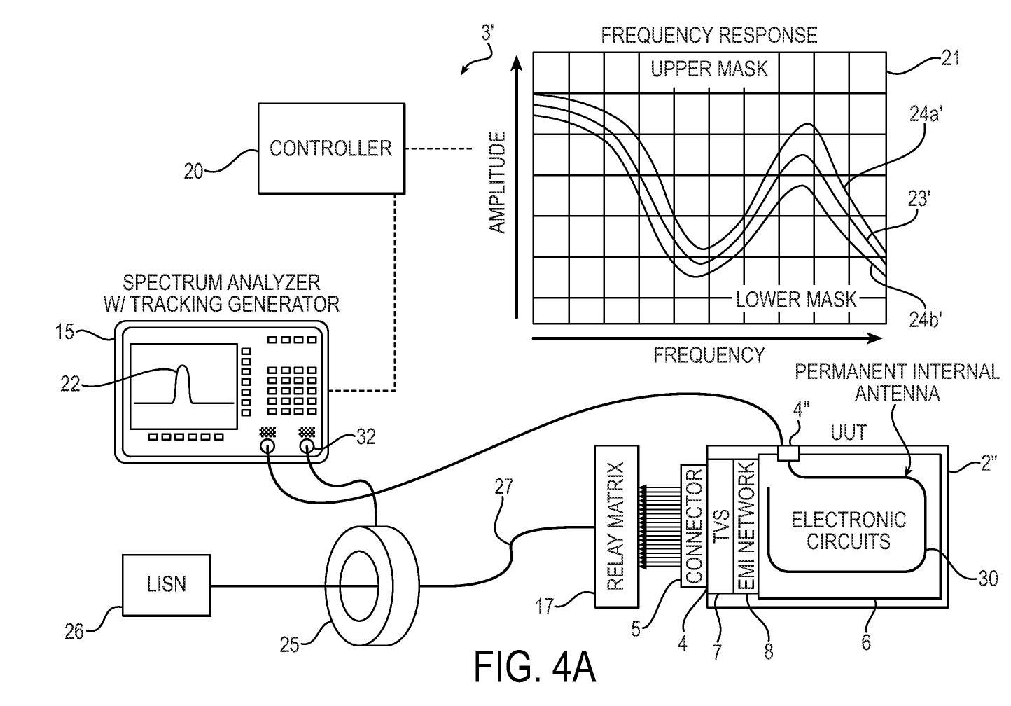

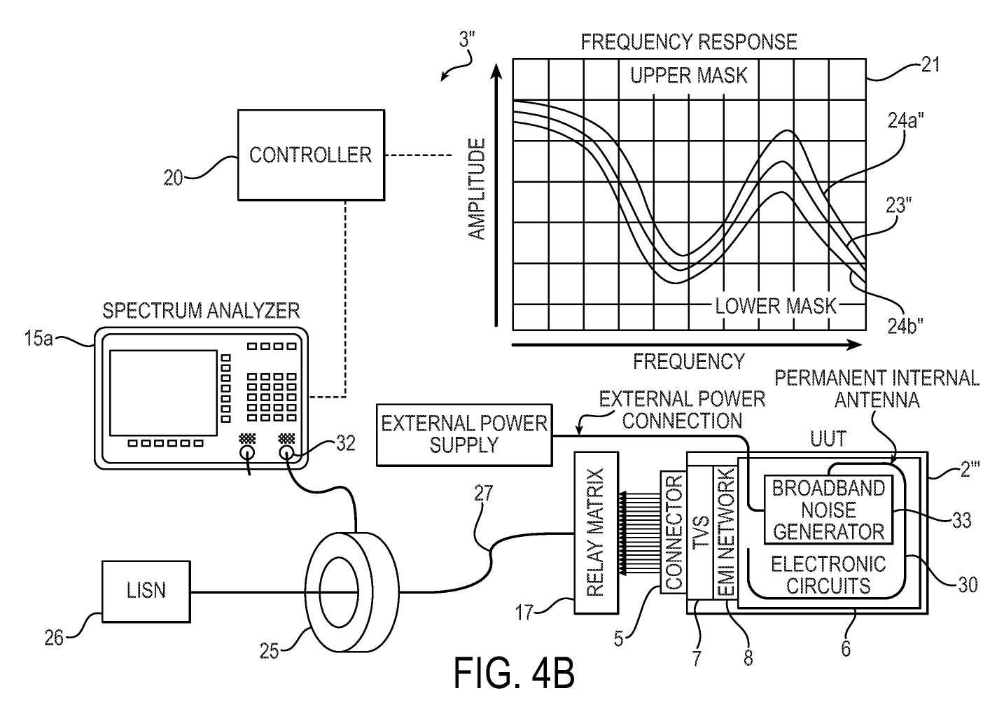

Moving now to FIG. 4A, illustrated is a block diagram of a second exemplary testing system 3′ for performing conducted emissions testing of a third exemplary UUT 2″ in accordance with the present disclosure. Conducted emissions are EMI events caused when radiated emissions within an item of a UUT are conducted onto a signal, data or power supply cable external to the UUT. A UUT passing the radiated emissions test may still fail the conducted emissions test. A UUT failing the conducted emissions test should be replaced with a fully operational LRU. During the conducted emissions test, the UUT 2″ can remain unpowered.

The testing system 3′ includes the devices of FIG. 3 for generating radiated emissions, and includes other devices for performing conducted emissions testing of the UUT 2″. The devices utilized during the conducted emissions testing include a current probe 25 and a line impedance stabilization network (LISN) 26, both of which enable measurement for possible emissions from the UUT 2″ that are conducted onto an external cable 27. In particular, the LISN 26 creates a known impedance and can provide an RF noise measurement port. The LISN 26 isolates unwanted RF signals from a power source, and can be used to predict conducted emission for diagnostic and pre-compliance testing.

A difference between the UUT 2″ and the UUT 2′ of FIG. 3 may include that the UUT 2″ has a separate input port 4″, and an internal antenna 30 for flooding the RF signal 22 swept over the prescribed frequency into the UUT 2″. The testing system 3′ tests the entire network 8 of the EMI components for conducted emissions.

In operation, the testing system 3′ generates radiated emissions within the UUT 2″. The signal generator/analyzer 15 directly inputs the RF signal 22, which is swept over the predetermined frequency range, to the input port 4″ of the UUT 2″. The internal antenna 30 is electrically coupled to the input port 4″ and receives the RF signal 22 and floods the RF signal 22 within the UUT 2″, thereby creating radiated emissions within the UUT 2″. Upon flooding the UUT 2″, the network 8 of the EMI components of the TVS 7 operate to minimize EMI.

The network 8 is electrically coupled to the connector 5 via pins, and the connector 5 electrically couples the network 8 to the relay matrix 17. The relay matrix 17 directs the return RF signal obtained at pin(s) coupled to the network 8 to the external cable 27. The external cable 27 may be a data cable for providing or retrieving data from the UUT 2″, a power cord that connects the UUT 2″ to an AC power source within the aircraft 1, or any other cable that may be used in the operation of the UUT 2″. The external cable 27 is operably coupled to the current probe 25 for scanning the external cable 27 for conducted emissions from the UUT 2″. The current probe 25 is designed to measure a current on a wire and may be a current transformer designed and suited for the intended purpose, a circular inductor with a ferrite core, etc. At high frequencies the current probe simply may be a 1 turn transformer, and at low frequencies the current probe may be a HALL-effect device. The current probe 25 is a non-intrusive scanning instrument and is generally arranged near or around the external cable 27. Upon scanning the external cable 27, the current probe 25 may pick up the emissions conducted onto the external cable 27 from the UUT 2″. The LISN 26 may be also used to monitor noise that the current probe 25 may miss. The LISN 26 is electrically coupled in series with the UUT 2″ and standardizes the input impedance of the UUT 2″ by providing input impedance at a predefined value, e.g., 50Ω. An input port of the LISN 26 is electrically coupled to the external cable 27 and receives conducted emissions from the UUT 2″. Conducted emissions obtained by the current probe 25 and the LISN 26 are input to an input port 32 of the signal generator/analyzer 15. The signal generator/analyzer 15 and/or the controller 20 (which may be internal or external to the signal generator/analyzer 15) receive the obtained conducted emissions over the prescribed frequency range.

The controller 20 creates a resultant signature 23′ representative of emissions on the cable 27 over the prescribed frequency range. The controller 20 then compares the resultant signature 23′ with a baseline signature of a known-good LRU having the same specification as the UUT 2″, and the comparison result can be output on the output device 21. The baseline signature may be stored in a memory internal to the signal generator/analyzer 15, the external controller 20, or at a remote location that is accessible by the signal generator/analyzer 15 and/or the controller 20.

If the resultant signature 23′ corresponds with the baseline signature within a prescribed envelope 24a′ and 24b′, it can be concluded that the EMI components of the UUT 2″ are within specification. If the resultant signature 23′ does not correspond with the baseline signature, it can be concluded that the UUT 2″ is not within specification and maintenance should be performed and/or it should be replaced with a fully operational LRU having the same specification with the UUT 2″.

FIG. 4B shows a block diagram of a third exemplary testing system 3″ for performing conducted emissions test of a network 8 of TVSs 7 of a fourth exemplary UUT 2′″. The testing system 3″ includes a signal analyzer 15a, relay matrix 17, a controller 20, an output device 21, a current probe 25, an LISN 26, and an external cable 27. A difference in the present embodiment illustrated in FIG. 4B from the previous embodiments is that the UUT 2′″ includes an internal broadband noise generator 33, which is powered by a power source (not shown). In the embodiment illustrated in FIG. 4B the broadband noise generator 33 generates an RF signal having a prescribed characteristic. This is in contrast to the previous embodiments where the signal analyzer 15 generated the RF signal. The TVSs 7 & network 8 process the RF signal, which produces a signal that makes its way to the external cable 27 via the relay matrix 17. The external cable 27 is communicatively coupled to the current probe 25 and the LISN 26, one or both of which can be used to obtain data corresponding to emissions conducted onto the external cable 27. The signal analyzer 15a then obtains conducted emissions over a desired frequency range from the current probe 25 and the LISN 26. The controller 20, which may be internal or external to the signal analyzer 15a, analyzes the collected conducted emissions based on an analysis method. More particularly, the controller 20 calculates a resultant signature 23″ based on the obtained conducted emissions over the desired frequency range. The controller 20 then compares the resultant signature 23″ with a baseline signature of a known good LRU having the same specifications as the UUT 2′″. The controller 20 then causes the output device 21 to provide the comparison result graphically or numerically. If the resultant signature 23″ corresponds with the baseline signature within a prescribed envelope 24a″, 24b″, then it can be concluded that the EMI components of the UUT 2′″ are within specification. If the resultant signature 23″ does not correspond with the baseline signature within the prescribed envelope 24a″, 24b″, then it can be concluded that the UUT 2′″ is not within specification and a maintenance procedure may be performed whereby the UUT 2′″ may be replaced with a fully operational LRU having the same specifications of the UUT 2′″.

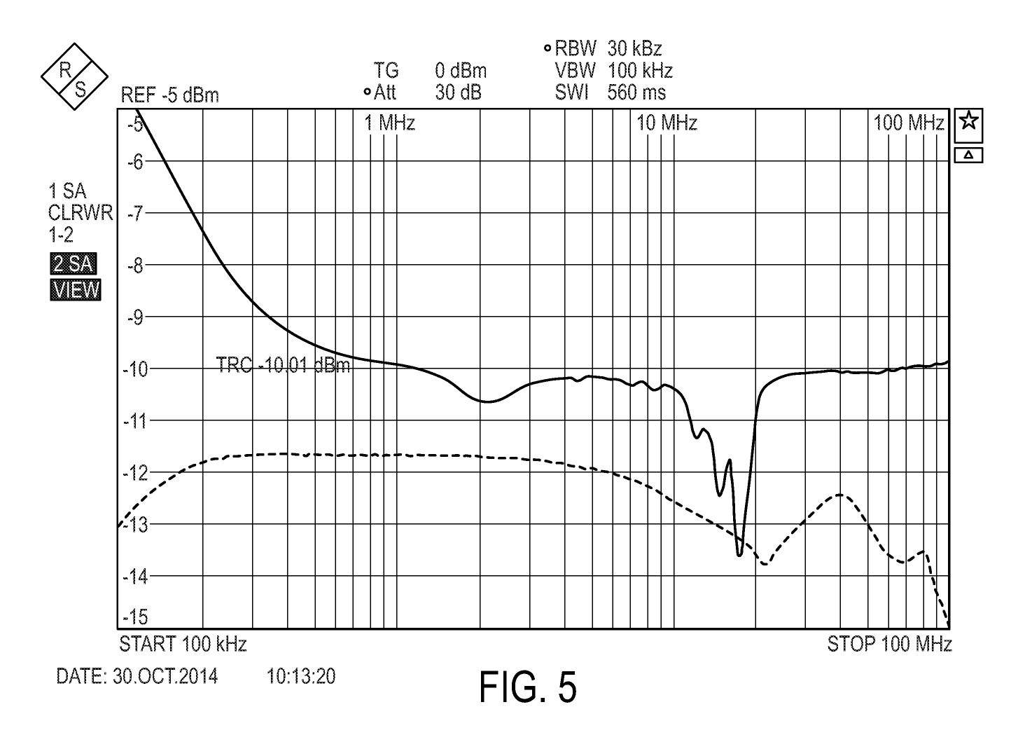

FIG. 5 is an exemplary baseline signature of a known good LRU having the same specifications as the UUT 2, 2′, 2″, 2′″. The baseline signature may be used for comparing an RF signal under analysis for EMC, where if a signature derived from the RF signal corresponds to the baseline signature within a predefined envelope 24a, 24a′, 24a″, 24b, 24b′, 24b″ (FIGS. 3, 4A and 4B) it can be concluded the EMI components of the UUT are operating within specification, and if the signature derived from the RF signal does not correspond to the baseline signature within the predefined envelope 24a, 24a′, 24a″, 24b, 24b′, 24b″ it can be concluded the UUT is out of specification.

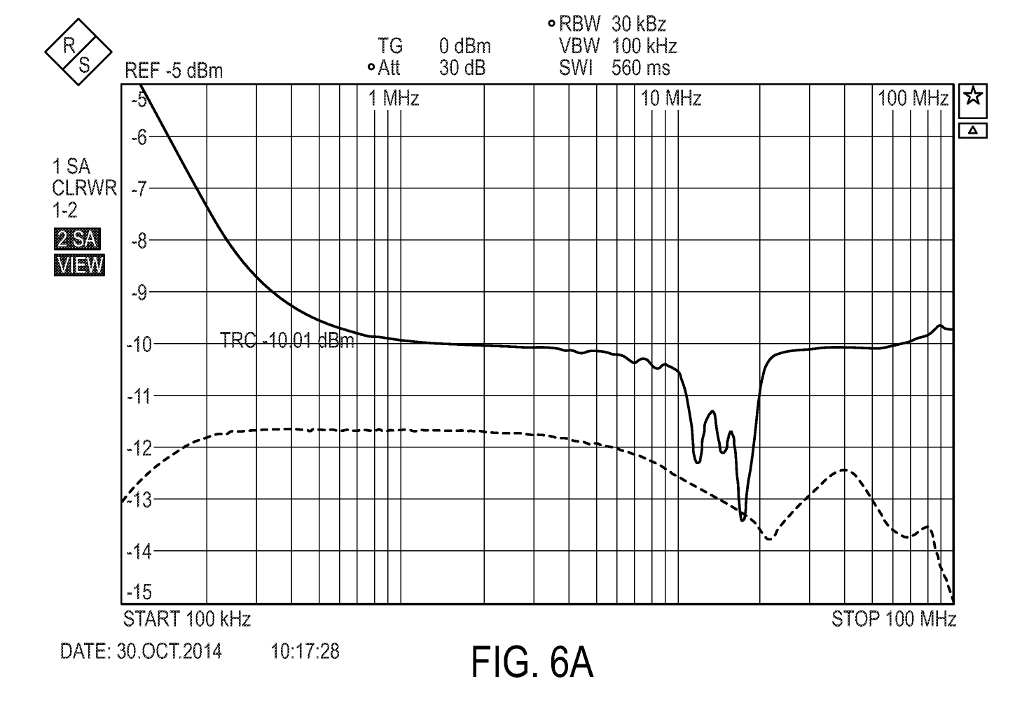

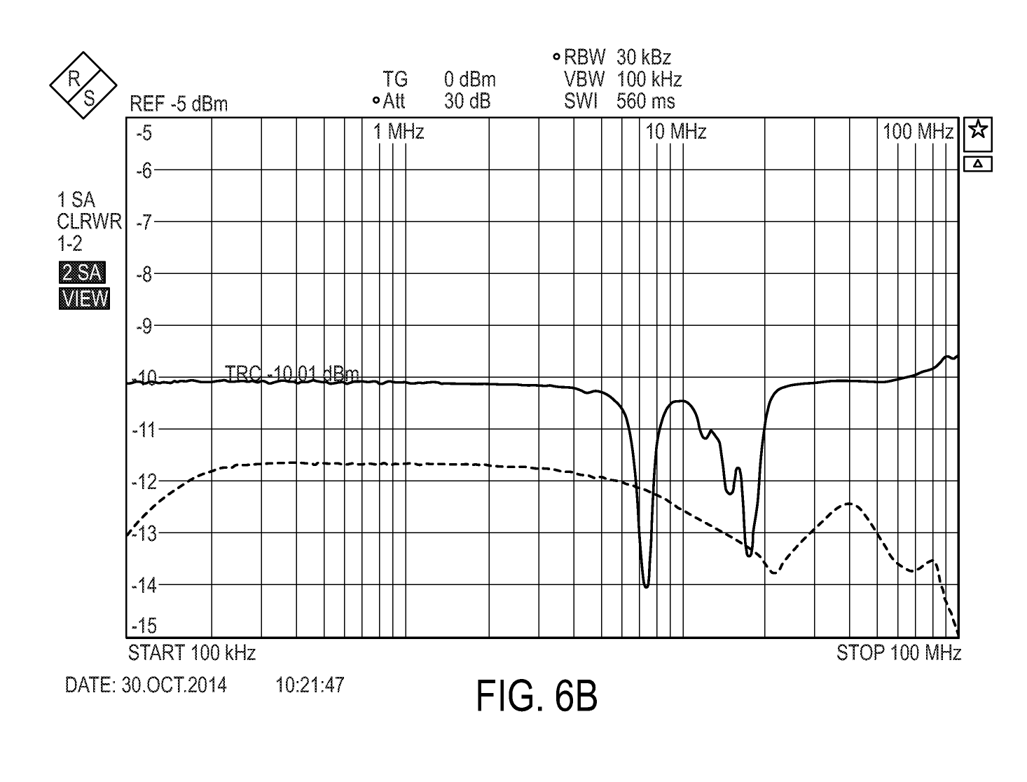

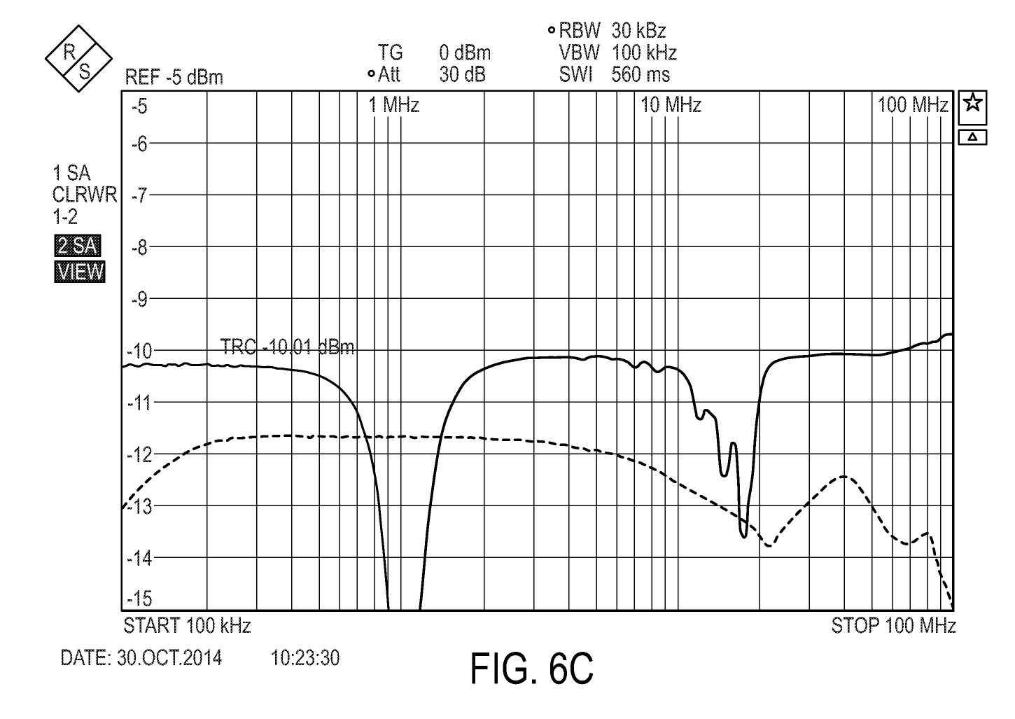

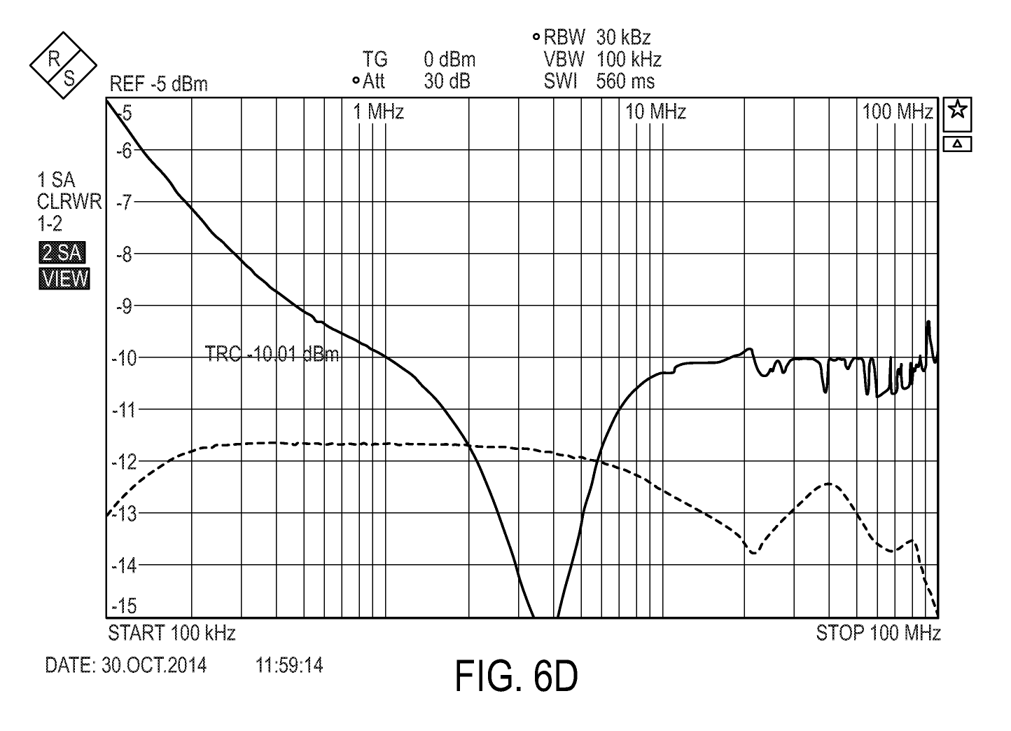

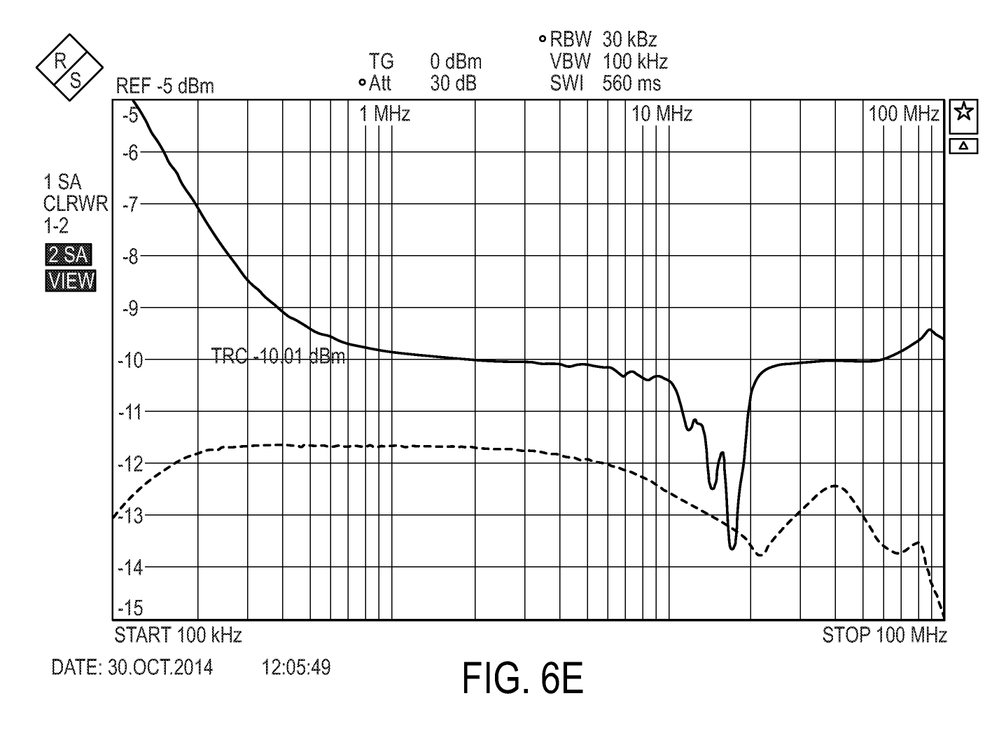

FIGS. 6A-6E are exemplary resultant signatures obtained after EMC testing of the network 8 of EMI components of the UUT 2″, 2′″ in accordance with the present disclosure. The illustrated resultant signatures were obtained when an EMI component within the network 8 failed due to EMI events. FIG. 6A shows a resultant signature when a ferrite bead 13 is shorted. Compared to the baseline signature of FIG. 5, the resultant signature lacks the dip around 2 MHz. FIG. 6B shows a resultant signature when a first parallel capacitor 11 is shorted. This resultant signature also lacks the dip around 2 MHz or the decay from 0 to 10 dB occurring over 100 KHz to 1 MHz. Further, the resultant signature shows a dip from 10 dB to 14 dB over 5 MHz to 10 MHz. FIG. 6C shows a resultant signature when a second capacitor 12 is shorted. The resultant signature shows no dip around 2 MHz, no decay over 100 KHz to 1 MHz, but includes a steep decay over 500 KHz to 3 MHz. FIG. 6D shows a resultant signature when the first parallel capacitor 11 is open. The resultant signature lacks the dip around 2 MHz, but shows a steep decay over 1 MHz to 3 MHz. Further, the resultant signature fails to show the triple dip over 10 MHz to 20 MHz, but instead, shows multiple small dips in a range of 1 dB over 20 MHz to 100 MHz. FIG. 6E shows a resultant signature when the second parallel capacitor 12 is open. This resultant signature shows no dip over 2 MHz, but a small rise at 90 MHz.

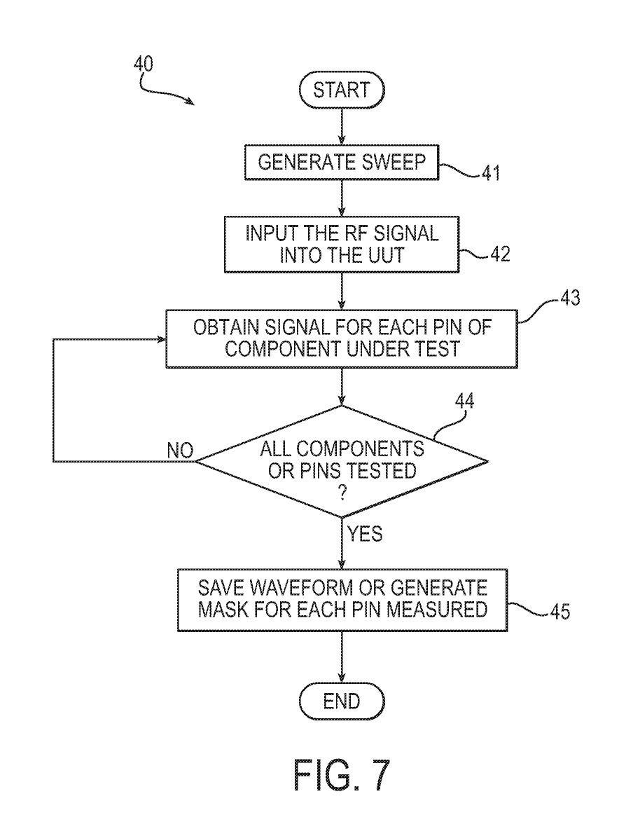

Moving now to FIG. 7, illustrated is a flow chart depicting the steps of an exemplary method 40 for obtaining a baseline signature of the EMI components of a fully operational UUT 2′ using the exemplary testing system 3 of FIG. 3 in accordance with the present disclosure. Beginning at step 41, the signal generator/analyzer 15 (e.g., an internal tracking generator of the signal generator/analyzer) generates an RF signal swept over a prescribed frequency range. The method then proceeds to step 42 where the signal generator/analyzer 15 inputs the RF signal to a reference UUT via the return loss bridge 16, the relay matrix 17, and the connector 5. The RF signal 22 enters the UUT 2′ and the electrical circuit 6.

Next at step 43 as each electrical circuit 6 is exposed to the RF signal the EMI components of the TVS 7 & NETWORK 8 filter the RF signal and a reflection of the filtered RF signal exits the reference UUT via the connector 5, and the signal generator/analyzer 15 receives the reflected signal via the relay matrix 17 and the return loss bridge 16. The return RF signal over the prescribed frequency range is obtained for each pin of the UUT that is connected to the EMI components.

Next, the method proceeds to step 44 where it is determined if the return RF signal has been obtained from each of the EMI components. If it is determined that the signal generator 15 has not obtained the return RF signal from each of the EMI components, the method reverts to step 43. If it is determined that the signal generator 15 has obtained the return RF signal from each of the EMI components, the method proceeds to step 45 where the waveform corresponding to the RF signal from each component is saved as the baseline signature.

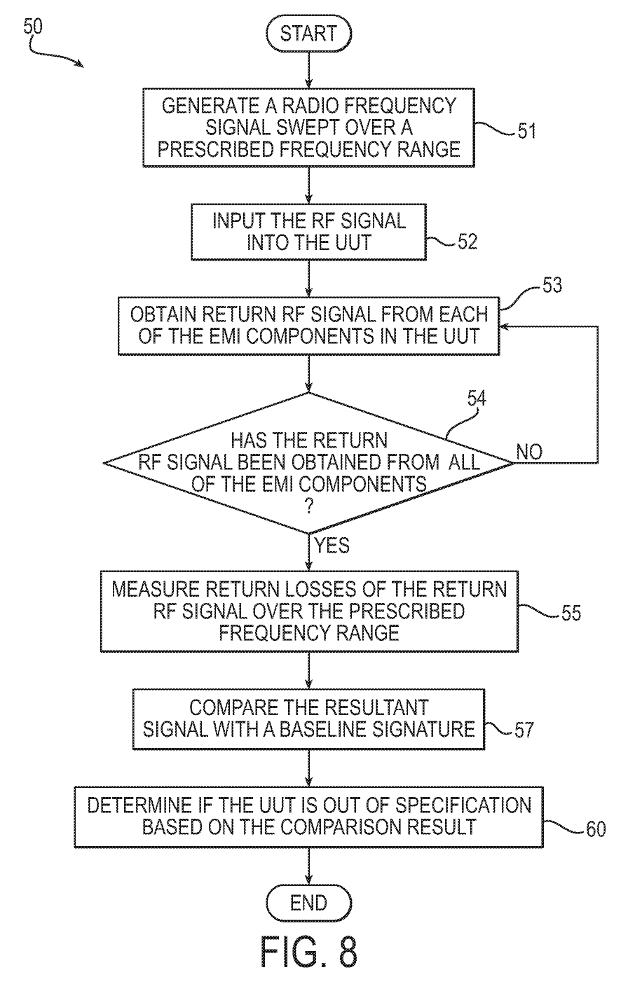

Moving now to FIG. 8, illustrated is a flow chart depicting the steps of an exemplary method 50 for performing radiated emissions test of the EMI components of a UUT 2′ using the exemplary testing system 3 of FIG. 3 in accordance with the present disclosure. As previously discussed, the exemplary testing system 3 includes a signal generator/analyzer 15, a return loss bridge 16, a relay matrix 17, a controller 20, and an output device 21. The testing system 3 is electrically coupled to the UUT 2′ via a connector 5 connected to the input and/or output port 4.

The method 50 begins at step 51 where the signal generator/analyzer 15 (e.g., an internal tracking generator of the signal generator/analyzer) generates an RF signal swept over a prescribed frequency range. The method then proceeds to step 52 where the signal generator/analyzer 15 inputs the RF signal to the UUT 2′ via the return loss bridge 16, the relay matrix 17, and the connector 5, and the RF signal 22 enters the UUT 2′.

Next at step 53 as each electrical circuit 6 is exposed to the RF signal the EMI components of the TVS 7 and network 8 filter the RF signal. A reflection of the filtered RF signal exits the UUT 2′ via the connector 5, and the signal generator/analyzer 15 receives the reflected signal via the relay matrix 17 and the return loss bridge 16. The return RF signal over the prescribed frequency range is obtained for each pin of the UUT that is connected to the EMI components. More particularly, the relay matrix 17 switches from one pin to another until the signal generator/analyzer 15 has obtained the filtered RF signals exiting (also referred to as the return RF signal) each pin of the connector 5. Next, the method proceeds to step 54 where it is determined if the return RF signal has been obtained from each of the EMI components. If it is determined that the signal generator 15 has not obtained the return RF signal from each of the EMI components, the method reverts to step 53. If it is determined that the signal generator 15 has obtained the return RF signal from each of the EMI components, the method proceeds to step 55.

At step 55, the controller 20 measures return loss of the return RF signal over the prescribed frequency range in accordance with the return loss method (e.g., using Equation 1) to obtain a signature. The resultant signature 23 is representative of the return loss of the return RF signal calculated over the prescribed frequency range. Then, the method proceeds to step 57 at which the controller 20 compares the resultant signature with a baseline signature of a known good LRU having the same specification as the UUT 2′. Next at step 60, the result of the comparison is output, where if the resultant signature 23 corresponds to the baseline signature within a prescribed envelope 24a, 24b, the EMI components of the UUT 2′ are considered to be within specification. If the resultant signature 23 does not correspond to the baseline signature within the prescribed envelope 24a, 24b, the UUT 2′ is considered to be out of specification. Then, the method 50 ends.

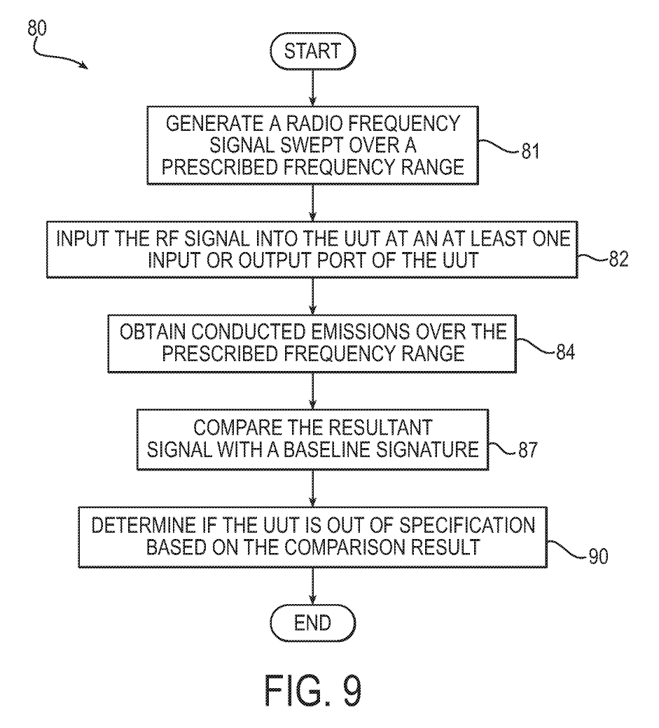

FIG. 9 is a flow chart depicting the steps of a second exemplary method 80 for EMC testing a UUT using the second exemplary testing system 3′ of FIG. 4A in accordance with the present disclosure. The testing system 3′ of FIG. 4A includes the signal generator/analyzer 15, the relay matrix 17, the controller 20, and the output device 21. The testing system 3′ further includes a current probe 25 and a line impedance stabilization network (LISN) 26 for performing conducted emissions test of the UUT 2″. The current probe 25 and the LISN 26 are used to scan for possible emissions from the UUT 2″ conducted onto an external cable 27.

The method 80 begins with step 81 at which the signal generator/analyzer 15 generates an RF signal swept over a prescribed frequency range. Next at step 82, the signal generator/analyzer 15 inputs the RF signal to the UUT 2″ via the input port 4″ of the UUT 2″, where the RF signal is distributed within the UUT 2″ via the internal antenna 30.

The method proceeds to step 84 where the EMI components of the TVS 7 & NETWORK 8 filter the RF signal, and a reflection of the filtered RF signal exits the UUT 2″ via the connector 5. Conducted emissions over the prescribed frequency range are obtained by the signal generator/analyzer 15 via the current probe 25 and the LISN 26. The resultant signature 23′ from the conducted emissions is collected by the signal generator/analyzer 15. Then, the method proceeds to step 87 at which the controller 20 compares the resultant signature with a baseline signature of a known good LRU having the same specification as the UUT 2″. Next at step 90 the result of the comparison is output, where if the resultant signature 23′ corresponds to the baseline signature within a prescribed envelope 24a′, 24b′, the EMI components of the UUT 2″ are considered to be within specification. If the resultant signature 23′ does not correspond to the baseline signature within the prescribed envelope 24a′, 24b′ the EMI components of the UUT 2″ are determined to be out of specification. Then, the method 80 ends.

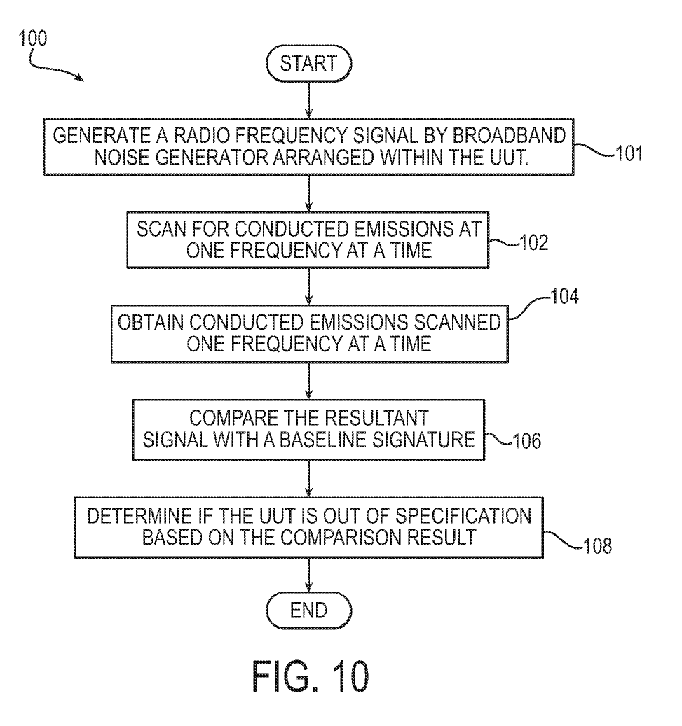

FIG. 10 is a flow chart depicting the steps of a third exemplary method 100 for performing conducted emissions testing of the fourth exemplary UUT 2′″ using the third exemplary testing system 3″ of FIG. 4B in accordance with the present disclosure. The testing system 3″ of FIG. 4B includes the signal analyzer 15a, the relay matrix 17, the controller 20, the output device 21, a current probe 25, and a line impedance stabilization network (LISN) 26. The testing system 3″ is electrically coupled to the UUT 2′″ having an internal broadband noise generator 33. Hence, under this method 100 the RF signal is generated by the internal broadband generator 33, not by the signal analyzer 15a. The signal analyzer 15a in turn is used to analyze the return RF signals and generate a characteristic signature for the UUT.

The method 100 begins with step 101 at which the RF signal is generated by a broadband noise generator 33 arranged within the UUT 2′″. The RF signal then is exposed to the electrical circuit 6, and the TVS 7 & NETWORK 8 arranged at the electrical circuit 6 then filters the RF signal. The filtered RF signal (also referred to as a return RF signal) exits the UUT 2′″ via the connector 5 of the UUT 2′″. The connector 5 electrically couples the TVS 7 and network 8 of the EMI components to the relay matrix 17, where the signal then is exposed to the external cable 27. The method proceeds to step 102 at which the current probe 25 and the LISN 26 scan the external cable 27 for emissions from the UUT 2′″. The method then continues to step 104 at which the conducted emissions are obtained over the desired frequency range.

The method then proceeds to step 106 at which the controller compares the conducted emissions with a baseline signature of a known good LRU having the same specifications as the UUT 2′″. The controller 20 then causes the output device 21 to provide the comparison result graphically or numerically. Thereafter, the method continues to step 108 at which it is determined, based on the comparison, if the UUT 2′″ is within specification. The UUT 2′″ may be said to be out of specification if resultant signature 23″ does not correspond to the baseline signature in a prescribed envelope 24a″, 24b″. If the resultant signature 23″ corresponds to the baseline signature within the prescribed envelope 24a″, 24b″, then it may be concluded that the UUT 2′″ is within specification. Then, the method 100 ends.

Although the invention has been shown and described with respect to a certain embodiment or embodiments, it is obvious that equivalent alterations and modifications will occur to others skilled in the art upon the reading and understanding of this specification and the annexed drawings. In particular regard to the various functions performed by the above described elements (components, assemblies, devices, compositions, etc.), the terms (including a reference to a “means”) used to describe such elements are intended to correspond, unless otherwise indicated, to any element which performs the specified function of the described element (i.e., that is functionally equivalent), even though not structurally equivalent to the disclosed structure which performs the function in the herein illustrated exemplary embodiment or embodiments of the invention. In addition, while a particular feature of the invention may have been described above with respect to only one or more of several illustrated embodiments, such feature may be combined with one or more other features of the other embodiments, as may be desired and advantageous for any given or particular application.

1. A method for testing a network of electromagnetic interference components within a unit under test (UUT) of an aircraft, the UUT having at least one of an input port or an output port electrically coupled to the network, the method comprising:
generating a radio frequency (RF) signal swept over a prescribed frequency range;
applying the generated RF signal to the UUT;
measuring a resultant signature at the at least one input port or output port;
comparing the measured resultant signature with a baseline signature corresponding to the respective at least one input port or output port, the baseline signature representing normal operation of the UUT; and
determining the UUT is out of specification when the measured signal and the baseline signature do not correspond to one another within a prescribed envelope.

2. The method according to claim 1, wherein measuring comprises using a signal generator/analyzer to analyze the resultant signature.

3. The method according to claim 1, wherein generating the RF signal comprises using a tracking generator to generate the RF signal at a frequency the signal generator/analyzer is tuned.

4. The method according to claim 1, wherein generating an RF signal comprises using a broadband noise generator to generate the RF signal.

5. The method according to claim 4, wherein using the broadband noise generator comprises using a broadband noise generator arranged within the UUT.

6. The method according to claim 1, wherein measuring the resultant signature comprises measuring a return loss of the applied generated RF signal over the prescribed frequency range.

7. The method according to claim 1, wherein the baseline signature comprises a return loss measured over the prescribed frequency range of a known good UUT.

8. The method according to claim 1, wherein applying generated RF signal comprises applying the generated RF signal to the UUT when power is removed from the UUT.

9. The method according to claim 1, wherein applying the generated RF signal comprises using an antenna to apply the generated RF signal to the UUT.

10. The method according to claim 9, wherein using the antenna comprises using an antenna arranged within the UUT.

11. A method for testing an electromagnetic interference component within a unit under test (UUT) of an aircraft, the UUT having at least one of an input port or an output port electrically coupled to the electromagnetic interference component, the method comprising:
applying to the at least one input port or output port a radio frequency signal swept over a prescribed frequency range;
measuring at the at least one input port or output port a return loss over the prescribed frequency range;
comparing the measured return loss with a baseline signature for the respective at least one input port or output port, the baseline signature representing a normal operation of the UUT; and
determining the UUT is out of specification when the measured return loss and the baseline signature differ by more than a prescribed value.

12. The method according to claim 11, wherein measuring comprises using a signal generator/analyzer to analyze the resultant signature.

13. The method according to claim 11, wherein measuring the resultant signature comprises measuring a return loss of the applied generated RF signal over the prescribed frequency range.

14. The method according to claim 11, wherein the baseline signature comprises a return loss measured over the prescribed frequency range of a known good UUT.

15. The method according to claim 11, wherein applying generated RF signal comprises applying the generated RF signal to the UUT when power is removed from the UUT.

16. A system for testing a network of electromagnetic interference and lightning components within a unit under test (UUT) of an aircraft, comprising:
a signal generator/analyzer configured to generate a radio frequency (RF) signal swept over a prescribed frequency range;
circuitry configured to input the RF signal into the UUT, the circuitry electrically coupleable to at least one input or output port of the UUT;
a scanning device operably coupled to the circuitry and configured to obtain a resultant signature detected at an at least one input or output port of the UUT;
a processor operably coupled to the scanning device and configured to compare the resultant signature to a baseline signature corresponding to the respective at least one input port or output port, the baseline signature representing normal operation of the UUT; and
an output device for providing the comparison result.

17. The system of claim 16, further comprising a directional coupler electrically coupleable to the circuitry, the at least one input or output port of the UUT, and the device.

18. The system of claim 16, further comprising an antenna operably coupled to the circuitry and configured to apply the generated radio frequency signal into the UUT.

19. A system for testing an electromagnetic interference component within a unit under test (UUT) of an aircraft, comprising:
circuitry configured to input a radio frequency signal swept over a prescribed frequency range into an at least one input or output port of the UUT, the circuitry electrically coupleable to at least one input or output port of the UUT; and
a device operably coupled to the circuitry and the at least one input or output port of the UUT and configured to measure and compare a resultant signature detected at the at least one input or output port of the UUT to a baseline signature corresponding to the respective at least one input port or output port, the baseline signature representing normal operation of the UUT.

20. The system of claim 19, further comprising a directional coupler electrically coupleable to the circuitry, the at least one input or output port of the UUT, and the device.
